(19) United States
(12) Patent Application Publication
(10) Pub. No.: US 2024/0373691 A1
(43) Pub. Date: Nov. 7, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Meng LI, Beijing (CN); Yao HUANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/289,368

(22) PCT Filed: Feb. 28, 2022
(86) PCT No.: PCT/CN2022/078409

§ 371 Date: Nov. 2, 2023

(51) Int. Cl. H10K 59/131; G09G 3/3233; H10K 59/121

(52) U.S. Cl. CPC H10K 59/131; G09G 3/3233; H10K 59/1213; H10K 59/1216; G09G 2300/0426; G09G 2300/0819; G09G 2300/0842; G09G 2300/0861; G09G 2310/08

(57) ABSTRACT

A display panel is provided. The display panel includes a light emitting unit and a pixel driving circuit. The pixel driving circuit includes a driving transistor, a fifth transistor and a sixth transistor, the fifth transistor includes a first electrode connected to a power line, a second electrode connected to a first electrode of the driving transistor and a gate electrode connected to a first enabling signal line, and the sixth transistor includes a first electrode connected to a second electrode of the driving transistor, a second electrode connected to a first electrode of the light emitting unit and a gate electrode connected to a second enabling signal line.

### CROSS-REFERENCE TO RELATED APPLICATIONS

The present application is a U.S. National Stage of International Application No. PCT/CN2022/078409 filed on Feb. 28, 2022, the entire contents of which are incorporated herein by reference for all purposes.

### TECHNICAL FIELD

The present disclosure relates to the field of display technology, in particular, to a display panel and a display device.

### BACKGROUND

In the related art, a pixel driving circuit in a display panel usually adopts a 7T1C structure, however, the 7T1C pixel driving circuit has a large layout area, which thus is not good for the production of a high pixel density display panel.

It is to be noted that the above information disclosed in the Background section is only for enhancement of understanding of the background of the present disclosure and therefore it may contain information that does not form the prior art that is already known to a person skilled in the art.

### SUMMARY

An aspect of the present disclosure provides a display panel, including a light emitting unit and a pixel driving circuit for driving the light emitting unit, wherein the pixel driving circuit includes: a driving transistor; a fifth transistor, including a first electrode connected to a power line, a second electrode connected to a first electrode of the driving transistor and a gate electrode connected to a first enabling signal line; and a sixth transistor, including a first electrode connected to a second electrode of the driving transistor, a second electrode connected to a first electrode of the light emitting unit and a gate electrode connected to a second enabling signal line. The display panel further includes: a base substrate; a first active layer, provided on a side of the base substrate, the first active layer including a third active part, a fifth active part, a sixth active part, the third active part being configured to form a channel region of the driving transistor, the fifth active part being configured to form a channel region of the fifth transistor, and the sixth active part being configured to form a channel region of the sixth transistor; and a first conductive layer, provided on a side, away from the base substrate, of the first active layer. The first conductive layer includes: the first enabling signal line, an orthographic projection of the first enabling signal line on the base substrate extending in a first direction and covering an orthographic projection of the fifth active part on the base substrate, and a part of the first enabling signal line being configured to form the gate electrode of the fifth transistor; the second enabling signal line, an orthographic projection of the second enabling signal line on the base substrate extending in the first direction and covering an orthographic projection of the sixth active part on the base substrate, and a part of the second enabling signal line being configured to form a gate electrode of the sixth transistor; and a first conductive part, an orthographic projection of the first conductive part on the base substrate covering the third active part, and the first conductive part being configured to form the gate electrode of the driving transistor.

In an exemplary embodiment of the present disclosure, the first active layer further includes: a seventh active part, connected between the third active part and the sixth active part, an orthographic projection of the seventh active part on the base substrate extending in a second direction, and the second direction intersecting the first direction. The first enabling signal line includes a plurality of enabling signal line sections, orthographic projections of the plurality of enabling signal line sections on the base substrate are spaced apart in the first direction and extend in the first direction. The orthographic projection of the seventh active part on the base substrate passes through a gap between orthographic projections, on the base substrate, of two of the enabling signal line sections adjacent in the first direction. The display panel further includes: a first control signal line, an orthographic projection of the first control signal line on the base substrate extending in the first direction, and the plurality of enabling signal line sections spaced part in the first direction being connected to a same first control signal line.

In an exemplary embodiment of the present disclosure, the fifth transistor is a P-type transistor, the pixel driving circuit further includes a first transistor of type N including a first electrode connected to an initial signal line, a second electrode connected to the first electrode of the light emitting unit, a gate electrode connected to a first reset signal line, and the first control signal line is reused as the first reset signal line. The display panel further includes: a second active layer, provided on a side, away from the base substrate, of the first conductive layer and including a first active part for forming a channel region of the first transistor; and a third conductive layer, provided on a side, away from the base substrate, of the second active layer and including the first reset signal line, an orthographic projection of the first reset signal line on the base substrate covering the orthographic projection of the first active part on the base substrate, and a part of the first reset signal line being configured to form a top gate electrode of the first transistor.

In an exemplary embodiment of the present disclosure, the first conductive layer further includes a plurality of projections provided and connected in one-to-one correspondence with the plurality of enabling signal line sections. An orthographic projection of the projection on the base substrate is provided between the orthographic projection of the enabling signal line section on the base substrate and the orthographic projection of the first reset signal line on the base substrate. The display panel further includes: a fourth conductive layer, provided on a side, away from the base substrate, of the third conductive layer and including a third bridge part, the third bridge part being connected to the projection and the first reset signal line respectively through via holes.

In an exemplary embodiment of the present disclosure, the orthographic projection of the second enabling signal line on the base substrate does not overlap with the orthographic projection of the first enabling signal line on the base substrate, and the orthographic projection of the first active part on the base substrate is provided between the orthographic projection of the second enabling signal line on the base substrate and the orthographic projection of the first enabling signal line on the base substrate.

In an exemplary embodiment of the present disclosure, in the first direction, the orthographic projection of the first active part on the base substrate is provided between an orthographic projection of the sixth active part on the base substrate and the orthographic projection of the fifth active part on the base substrate.

In an exemplary embodiment of the present disclosure, the first direction is a row direction, the second direction is a column direction, the display panel includes a plurality of repetition units arranged in the row direction and the column direction, the repetition units each includes two pixel driving circuits, the two pixel driving circuits include a first pixel driving circuit and a second pixel driving circuit arranged in the row direction, and the first pixel driving circuit and the second pixel driving circuit are provided in mirror symmetry. The plurality of enabling signal line sections are provided in correspondence with the plurality of repetition units, the orthographic projection of the enabling signal line section on the base substrate covers the orthographic projections, on the base substrate, of two fifth active parts of a corresponding repetition unit.

In an exemplary embodiment of the present disclosure, the third conductive layer further includes: the initial signal line, including a plurality of initial signal line sections, orthographic projections of the plurality of initial signal line sections on the base substrate being spaced apart in the first direction and extending in the first direction. The second active layer further includes: a tenth active part, connected to the first active part, an orthographic projection of at least part of the tenth active part on the base substrate being provided at a gap between orthographic projections, on the base substrate, of two of the initial signal line sections adjacent in the first direction. The display panel further includes: a fourth conductive layer, provided on a side, away from the base substrate, of the third conductive layer and including a fourth bridge part, an orthographic projection of the fourth bridge part on the base substrate extending along the first direction, the fourth bridge part being connected to two of the initial signal line sections adjacent in the first direction through via holes respectively and being connected to the tenth active part provided between the two of the initial signal line sections adjacent in the first direction through a vial hole.

In an exemplary embodiment of the present disclosure, the orthographic projection of the initial signal line section on the base substrate is provided between the orthographic projection of the first conductive part on the base substrate and the orthographic projection of the first reset signal line on the base substrate, the plurality of initial signal line sections are provided in correspondence with the plurality of enabling signal line sections, and the orthographic projection of the initial signal line section on the base substrate is at least partially overlapped with the orthographic projection of a corresponding enabling signal line section on the base substrate.

In an exemplary embodiment of the present disclosure, the pixel driving circuit further includes: a fourth transistor, including a first electrode connected to a data line, a second electrode connected to the first electrode of the driving transistor and a gate electrode connected to a second gate line. The first active layer further includes: a fourth active part, configured to form a channel region of the fourth transistor. The first conductive layer further includes: the second gate line, an orthographic projection of the second gate line on the base substrate extending in the first direction and covering an orthographic projection of the fourth active part on the base substrate, and a part of the second gate line being configured to form the gate electrode of the fourth transistor. The orthographic projection of the second gate line on the base substrate is provided at a side, away from the orthographic projection of the first enabling signal line on the base substrate, of the orthographic projection of the first conductive part on the base substrate.

In an exemplary embodiment of the present disclosure, the pixel driving circuit further includes: a second transistor, including a first electrode connected to the gate electrode of the driving transistor, a second electrode connected to the second electrode of the driving transistor and a gate electrode connected to a first gate line. The display panel further includes: a second active layer, provided on a side, away from the base substrate, of the first conductive layer, and including a second active part configured to form a channel region of the second transistor; and a third conductive layer, provided on a side, away from the base substrate, of the second active layer, and including the first gate line, an orthographic projection of the first gate line on the base substrate extending in the first direction and covering an orthographic projection of the second active part on the base substrate, and a part of the first gate line being configured to form a top gate of the second transistor. The orthographic projection of the first gate line on the base substrate is provided between the orthographic projection of the second gate line on the base substrate and the orthographic projection of the first conductive part on the base substrate.

In an exemplary embodiment of the present disclosure, the pixel driving circuit further includes: a first transistor, including a first electrode connected to an initial signal line, a second electrode connected to the first electrode of the light emitting unit and a gate electrode connected to a first reset signal line; a second transistor, including a first electrode connected to the gate electrode of the driving transistor, a second electrode connected to the second electrode of the driving transistor, and a gate electrode connected to a first gate line; a fourth transistor, including a first electrode connected to a data line, a second electrode connected to the first electrode of the driving transistor and a gate electrode connected to a second gate line; and a capacitor, including a first electrode connected to the gate electrode of the driving transistor and a second electrode connected to the power line. The first transistor and the second transistor are N-type transistors and the driving transistor, the fourth transistor, the fifth transistor and the sixth transistor are P-type transistors.

In an exemplary embodiment of the present disclosure, the first direction is a row direction, the display panel includes a plurality of repetition units arranged in the row direction and a column direction, the repetition units each includes two pixel driving circuits, the two pixel driving circuits include a first pixel driving circuit and a second pixel driving circuit arranged in the row direction, and the first pixel driving circuit and the second pixel driving circuit are provided in mirror symmetry. The pixel driving circuit further includes a capacitor including a first electrode connected to the gate electrode of the driving transistor and a second electrode connected to the power line. The display panel further includes: a second conductive layer, provided on a side, away from the base substrate, of the first conductive layer and including a second conductive part, an orthographic projection of the second conductive part on the base substrate being at least partially overlapped with the orthographic projection of the first conductive part on the base substrate, and the second conductive part being configured to form the second electrode of the capacitor; and a fifth conductive layer, provided on a side, away from the base substrate, of the second conductive layer and including the power line, an orthographic projection of the power line on the base substrate extending in a second direction, and the second direction intersecting the first direction. In a same repetition unit, the second conductive part in the first pixel driving circuit is connected to the second conductive part in the second pixel driving circuit, and each column of the pixel driving circuits corresponds to one power line, and in the repetition units adjacent in the row direction, adjacent power lines are connected to each other.

In an exemplary embodiment of the present disclosure, the second conductive layer further includes a first connection part, and in the same repetition unit, adjacent second conductive parts are connected by the first connection part, the first active layer further includes a twelfth active part connected to an end, away from the third active part, of the fifth active part, the display panel further includes a fourth conductive layer provided between the second conductive layer and the fifth conductive layer, the fourth conductive layer further includes a plurality of first bridge parts, the plurality of first bridge parts are provided in correspondence with the plurality of the repetition units, the first bridge part is connected to the first connection part and the twelfth active parts respectively through via holes and is connected to the power line through a via hole.

In an exemplary embodiment of the present disclosure, the first bridge part is mirror-symmetrical with respect to a mirror-symmetrical plane of the first pixel driving circuit and the second pixel driving circuit.

In an exemplary embodiment of the present disclosure, the pixel driving circuit further includes: a first transistor, including a first electrode connected to an initial signal line, a second electrode connected to the first electrode of the light emitting unit and a gate electrode connected to a first reset signal line; and a second transistor, including a first electrode connected to the gate electrode of the driving transistor, a second electrode connected to the second electrode of the driving transistor and a gate electrode connected to a first gate line. The display panel further includes: a second active layer, provided on a side, away from the base substrate, of the first conductive layer, and including a first active part for forming a channel region of the first transistor and a second active part for forming a channel region of the second transistor; a third conductive layer, provided on a side, away from the base substrate, of the second active layer; a fourth conductive layer, provided on a side, away from the base substrate, of the third conductive layer; and a fifth conductive layer, provided on a side, away from the base substrate, of the fourth conductive layer, the fifth conductive layer including the power line, the power line including a first extension part and a second extension part, a dimension, in the first direction, of an orthographic projection of the first extension part on the base substrate being larger than a dimension, in the first direction, of an orthographic projection of the second extension part on the base substrate, and the orthographic projection of the first extension part on the base substrate covering an orthographic projection of the first active part on the base substrate and an orthographic projection of the second active part on the base substrate.

In an exemplary embodiment of the present disclosure, the pixel driving circuit further includes: a first transistor, including a first electrode connected to an initial signal line, a second electrode connected to the first electrode of the light emitting unit and a gate electrode connected to a first reset signal line; and a second transistor, including a first electrode connected to the gate electrode of the driving transistor, a second electrode connected to the second electrode of the driving transistor and a gate electrode connected to a first gate line. The display panel further includes: a second active layer, provided on a side, away from the base substrate, of the first conductive layer, and including a first active part for forming a channel region of the first transistor and a second active part for forming a channel region of the second transistor; and a second conductive layer, provided between the first conductive layer and the second active layer, the second conductive layer including: a third gate line, an orthographic projection of the third gate line on the base substrate extending in the first direction and covering an orthographic projection of the second active part on the base substrate, and a part of the third gate line being configured to form a bottom gate of the second transistor; and a second reset signal line, an orthographic projection of the second reset signal line on the base substrate extending in the first direction and covering an orthographic projection of the first active part on the base substrate, and a part of the second reset signal line is configured to form a bottom gate of the first transistor.

In an exemplary embodiment of the present disclosure, the display panel further includes: an electrode layer, provided on a side, away from the base substrate, of the first conductive layer, and including a plurality of electrode parts, the electrode part being configured to form the first electrode of the light emitting unit. The plurality of electrode parts includes a plurality of R electrode parts, a plurality of G electrode parts, a plurality of B electrode parts. In a plurality of electrode parts connected to a same row of the pixel driving circuits, the R electrode part, the G electrode part, the B electrode part, the G electrode part are arranged in a row direction in turn. In two adjacent columns of the pixel driving circuits, a plurality of R electrode parts and a plurality of B electrode parts connected to a same column of the pixel driving circuits, the R electrode part and the B electrode part connected to the same column of the pixel driving circuits are arranged in a column direction in turn, and a plurality of G electrode parts are connected to another column of the pixel driving circuits. A minimum distance, in the column direction, between orthographic projections, on the base substrate, of two G electrode parts at least partially connected to adjacent rows of the pixel driving circuits and connected to a same column of the pixel driving circuits is less than a dimension, in the column direction, of an orthographic projection of the R electrode part on the base substrate or a dimension, in the column direction, of the orthographic projection of the B electrode part on the base substrate.

In an exemplary embodiment of the present disclosure, the display panel further includes: an electrode layer, provided on a side, away from the base substrate, of the first conductive layer, and including a plurality of electrode parts, the electrode part being configured to form the first electrode of the light emitting unit. The plurality of electrode parts includes a plurality of R electrode parts, a plurality of G electrode parts, a plurality of B electrode parts. In a plurality of electrode parts connected to a same row of the pixel driving circuits, the R electrode part, the G electrode part, the B electrode part, the G electrode part are arranged in a row direction in turn. In two adjacent columns of the pixel driving circuits, a plurality of R electrode parts and a plurality of B electrode parts connected to a same column of the pixel driving circuits, the R electrode part and the B electrode part connected to the same column of the pixel driving circuits are arranged in a column direction in turn, and a plurality of G electrode parts are connected to another column of the pixel driving circuits. A minimum distance, in the column direction, between orthographic projections, on the base substrate, of two G electrode parts at least partially connected to adjacent rows of the pixel driving circuits and connected to a same column of the pixel driving circuits is greater than a dimension, in the column direction, of an orthographic projection of the R electrode part on the base substrate or a dimension, in the column direction, of the orthographic projection of the B electrode part on the base substrate.

An aspect of the present disclosure provides a display device, including the display panel described above.

It should be understood that the above general description and the detailed descriptions that follow are only exemplary and explanatory and do not limit the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principle of the present disclosure. It will be apparent that the accompanying drawings in the following description are only some embodiments of the present disclosure, and that according to these accompanying drawings, a person skilled in the art may obtain other accompanying drawings without creative effort.

FIG. 1 is a schematic diagram of a circuit structure of a pixel driving circuit in the related art;

FIG. 2 is a timing diagram of each node in a driving method of the pixel driving circuit of FIG. 1;

FIG. 3 is a schematic diagram of a structure of a pixel driving circuit according to an exemplary embodiment of the present disclosure;

FIG. 4 is a timing diagram of each node in a driving method of the pixel driving circuit in FIG. 3;

FIG. 5 is a structure layout diagram of a display panel according to an exemplary embodiment of the present disclosure;

FIG. 6 is a structure layout diagram of a first active layer in FIG. 5;

FIG. 7 is a structure layout diagram of a first conductive layer in FIG. 5;

FIG. 8 is a structure layout diagram of a second conductive layer in FIG. 5;

FIG. 9 is a structure layout diagram of a second active layer in FIG. 5;

FIG. 10 is a structure layout diagram of a third conductive layer in FIG. 5;

FIG. 11 is a structure layout diagram of a fourth conductive layer in FIG. 5;

FIG. 12 is a structure layout diagram of a fifth conductive layer in FIG. 5;

FIG. 13 is a structure layout diagram of an electrode layer in FIG. 5;

FIG. 14 is a structure layout diagram of a first active layer and a first conductive layer in FIG. 5;

FIG. 15 is a structure layout diagram of a first active layer, a first conductive layer and a second conductive layer in FIG. 5;

FIG. 16 is a structure layout diagram of a first active layer, a first conductive layer, a second conductive layer and a second active layer in FIG. 5;

FIG. 17 is a structure layout diagram of a first active layer, a first conductive layer, a second conductive layer, a second active layer and a third conductive layer in FIG. 5;

FIG. 18 is a structure layout diagram of a first active layer, a first conductive layer, a second conductive layer, a second active layer, a third conductive layer and a fourth conductive layer in FIG. 5;

FIG. 19 is a structure layout diagram of a first active layer, a first conductive layer, a second conductive layer, a second active layer, a third conductive layer, a fourth conductive layer and a fifth conductive layer in FIG. 5;

FIG. 20 is a structure layout diagram of a display panel according to another exemplary embodiment of the present disclosure;

FIG. 21 is a structure layout diagram of an electrode layer in FIG. 20;

FIG. 22 is a partial section view of a display panel taken along a dotted line AA in FIG. 5;

FIG. 23 is a structure layout diagram of a light shielding layer of a display panel according to another exemplary embodiment of the present disclosure;

FIG. 24 is a structure layout diagram of a light shielding layer and a first active layer of a display panel according to another exemplary embodiment of the present disclosure; and

FIG. 25 is a structure layout diagram of a light shielding layer, a first active layer and a first conductive layer of a display panel according to another exemplary embodiment of the present disclosure.

### DETAILED DESCRIPTION

Example embodiments will now be described more fully with reference to the accompanying drawings. Example embodiments, however, may be embodied in various forms and should not be construed as being limited to the examples set forth herein; rather, these embodiments are provided so that the present disclosure will be thorough and complete, and the concept of example embodiments would be fully conveyed to a person skilled in the art. The same reference numerals in the drawings denote the same or similar structures, and thus their detailed descriptions will be omitted.

The terms “a”, “an”, “the” or the like are used to indicate the presence of one or more elements/components/etc.; and the terms “including” and “having” are used to indicate an open-ended inclusive meaning and that additional elements/components/etc. may be present in addition to the listed elements/components/etc.

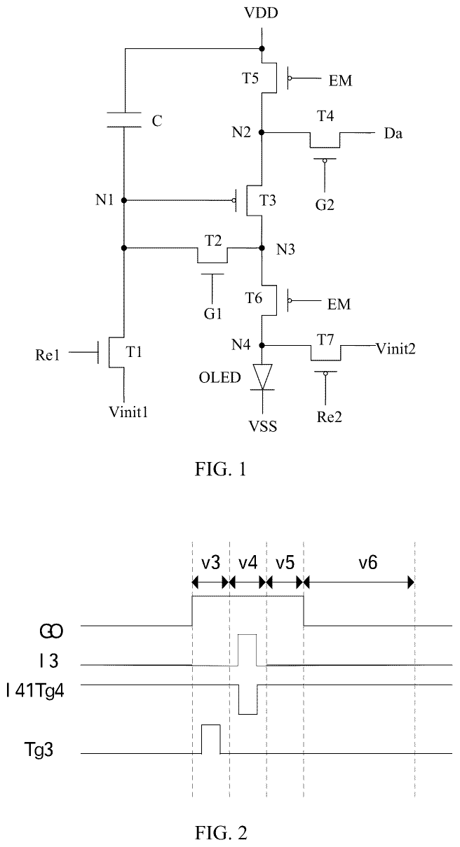

FIG. 1 is a schematic diagram of a circuit structure of a pixel driving circuit in the related art. The pixel driving circuit may include a driving transistor T3, a first transistor T1, a second transistor T2, a fourth transistor T4, a fifth transistor T5, a sixth transistor T6, a seventh transistor T7 and a capacitor C. A first electrode of the fourth transistor T4 is connected to a data signal terminal Da, a second electrode of the fourth transistor T4 is connected to a first electrode of the driving transistor T3, and a gate electrode of the fourth transistor T4 is connected to a second gate driving signal terminal G2. A first electrode of the fifth transistor T5 is connected to a first power supply terminal VDD, a second electrode of the fifth transistor T5 is connected to the first electrode of the driving transistor T3, and a gate electrode of the fifth transistor T5 is connected to an enabling signal terminal EM. A gate electrode of the driving transistor T3 is connected to a first node N1, the first electrode of the driving transistor T3 is connected to a second node N2, and a second electrode of the driving transistor T3 is connected to a third node N3. A first electrode of the second transistor T2 is connected to the first node N1, a second electrode of the second transistor T2 is connected to the second electrode of the driving transistor T3, and a gate electrode of the second transistor T2 is connected to a first gate driving signal terminal G1. A first electrode of the sixth transistor T6 is connected to the second electrode of the driving transistor T3, a second electrode of the sixth transistor T6 is connected to a fourth node N4, and a gate electrode of the sixth transistor T6 is connected to an enabling signal terminal EM. A first electrode of the seventh transistor T7 is connected to the fourth node N4, a second electrode of the seventh transistor T7 to a second initial signal terminal Vinit2, and a gate electrode of the seventh transistor T7 is connected to a second reset signal terminal Re2. A first electrode of the first transistor T1 is connected to the first node N1, a second electrode of the first transistor T1 is connected to a first initial signal terminal Vinit1, and a gate electrode of the first transistor T1 is connected to a first reset signal terminal Re1. A first electrode of the capacitor C is connected to the first node N1, and a second electrode of the capacitor C is connected to the first power supply terminal VDD. The pixel driving circuit may be connected to a light emitting unit OLED for driving the light emitting unit OLED to emit light. The light emitting unit OLED may be connected between the second electrode of the sixth transistor T6 and a second power supply terminal VSS. The first transistor T1 and the second transistor T2 may be N-type transistors, for example, the first transistor T1 and the second transistor T2 may be N-type metal oxide transistors having a small leakage current so as to prevent a charge at the first node N1 from leaking through the first transistor T1 and the second transistor T2 during a light emitting phase. Meanwhile, the driving transistor T3, the fourth transistor T4, the fifth transistor T5, the sixth transistor T6, and the seventh transistor T7 may be P-type transistors, for example, the driving transistor T3, the fourth transistor T4, the fifth transistor T5, the sixth transistor T6, and the seventh transistor T7 may be P-type low-temperature polycrystalline silicon transistors having a high carrier mobility so as to facilitating the realization of a display panel with high resolution, high response speed, high pixel density, and high aperture ratio. The first initial signal terminal and the second initial signal terminal may output the same or different voltage signals according to an actual situation.

FIG. 2 is a timing diagram of each node in a driving method of the pixel driving circuit of FIG. 1, in which G1 indicates the timing of the first gate driving signal terminal G1, G2 indicates the timing of the second gate driving signal terminal G2, Re1 indicates the timing of the first reset signal terminal Re1, Re2 indicates the timing of the second reset signal terminal Re2, and EM indicates the timing of the enabling signal terminal EM. The driving method of the pixel driving circuit may include a reset phase t1, a compensation phase t2, a buffer phase t3 and a light emitting phase t4. In the reset phase t1, the first reset signal terminal Re1 outputs a high level signal, the first transistor T1 is turned on, and the first initial signal terminal Vinit1 inputs an initial signal to the first node N1. In the compensation phase t2, the first gate driving signal terminal G1 outputs a high level signal, the second gate driving signal terminal G2 outputs a low level signal, the fourth transistor T4 and the second transistor T2 are turned on, and at the same time, the data signal terminal Da outputs a driving signal to write a compensation voltage Vdata+Vth to the first node N1, where Vdata is the voltage of the driving signal and Vth is the threshold voltage of the driving transistor T3, in addition, the second reset signal terminal outputs a low signal, the seventh transistor T7 is turned on, and the second initial signal terminal Vinit2 inputs an initial signal to the fourth node N4. In the buffer phase t3, the first gate driving signal terminal G1 and the first reset signal terminal Re1 output a low level signal, and the second gate driving signal terminal G2 and the second reset signal terminal Re2 output a high level signal. In the light emitting phase t4, the enabling signal terminal EM outputs a low level signal, the sixth transistor T6 and the fifth transistor T5 are turned on, and the light emitting unit OLED emits light under the action of the voltage Vdata+Vth stored in the capacitor C. However, the above-mentioned pixel driving circuit has a large layout area.

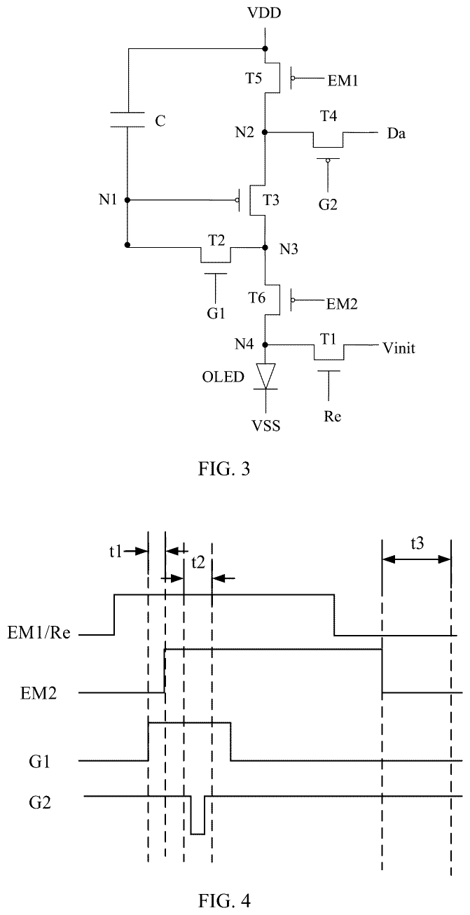

In view of the above, an exemplary embodiment of the present disclosure first provides a pixel driving circuit. FIG. 3 is a schematic diagram of a structure of a pixel driving circuit according to an exemplary embodiment of the present disclosure. The pixel driving circuit may include a driving transistor T3, a first transistor T1, a second transistor T2, a fourth transistor T4, a fifth transistor T5, a sixth transistor T6, and a capacitor C. A first electrode of the fourth transistor T4 is connected to a data signal terminal Da, a second electrode of the fourth transistor T4 is connected to a first electrode of the driving transistor T3, and the gate terminal of the fourth transistor T4 is connected to a second gate driving signal terminal G2. A first electrode of the fifth transistor T5 is connected to a first power supply terminal VDD, a second electrode of the fifth transistor T5 is connected to the first electrode of the driving transistor T3, and a gate electrode of the fifth transistor T5 is connected to a first enabling signal terminal EM1. A gate electrode of the driving transistor T3 is connected to a first node N1, the first electrode of the driving transistor T3 is connected to a second node N2, and a second electrode of the driving transistor T3 is connected to a third node N3. A first electrode of the second transistor T2 is connected to the first node N1, a second electrode of the second transistor T2 is connected to the second electrode of the driving transistor T3, and a gate electrode of the second transistor T2 is connected to a first gate driving signal terminal G1. A first electrode of the sixth transistor T6 is connected to the second electrode of the driving transistor T3, a second electrode of the sixth transistor T6 is connected to a fourth node N4, a gate electrode of the sixth transistor T6 is connected to a second enabling signal terminal EM2. A second electrode of the first transistor T1 is connected to the fourth node N4, a first electrode of the first transistor T1 is connected to an initial signal terminal Vinit, and a gate electrode of the first transistor T1 is connected to a reset signal terminal Re. A first electrode of the capacitor C is connected to the first node N1, and a second electrode of the capacitor C is connected to the first power supply terminal VDD. The pixel driving circuit may be connected to a light emitting unit OLED for driving the light emitting unit OLED to emit light. The light emitting unit OLED may be connected between the second electrode of the sixth transistor T6 and the second power supply terminal VSS. The first transistor T1 and the second transistor T2 may be N-type transistors, and the driving transistor T3, the fourth transistor T4, the fifth transistor T5, and the sixth transistor T6 may be P-type transistors. The first enable signal terminal EM1 and the reset signal terminal Re may be equipotential nodes, for example, the first enable signal terminal EM1 may be multiplexed as the reset signal terminal Re.

FIG. 4 is a timing diagram of each node in a driving method of the pixel driving circuit in FIG. 3, in which G1 indicates the timing of the first gate driving signal terminal G1, G2 indicates the timing of the second gate driving signal terminal G2, Re indicates the timing of the reset signal terminal Re, EM1 indicates the timing of the first enabling signal terminal EM1, and EM2 indicates the timing of the second enabling signal terminal EM2. The driving method of the pixel driving circuit may include a reset phase t1, a compensation phase t2 and a light emitting phase t3. In the reset phase t1, the reset signal terminal Re and the first gate driving signal terminal G1 output a high level signal, the second enabling signal terminal EM2 outputs a low level signal, the first transistor T1, the second transistor T2 and the sixth transistor T6 are turned on, the initial signal terminal Vinit inputs an initial signal to the first node N1 and the fourth node N4. In the compensation phase t2, the first gate driving signal terminal G1 outputs a high level signal, the second gate driving signal terminal G2 outputs a low level signal, the fourth transistor T4 and the second transistor T2 are turned on, and at the same time the data signal terminal Da outputs a driving signal to write the compensation voltage Vdata+Vth to the first node N1, where Vdata is the voltage of the driving signal and Vth is the threshold voltage of the driving transistor T3. In the light emitting phase t3, the first enabling signal terminal EM1 and the second enabling signal terminal EM2 output low level signals, the sixth transistor T6 and the fifth transistor T5 are turned on and the light emitting unit OLED emits light under the action of the voltage Vdata+Vth stored in the capacitor C.

The formula of the output current of the driving transistor is as follows:

I=(μWCox/2L)(Vgs−Vth)²

where I is the output current of the driving transistor, μ is the carrier mobility, Cox is the gate capacitance per unit area, W is the width of the channel of the driving transistor, L is the length of the channel of the driving transistor, Vgs is the gate-source voltage difference of the driving transistor, and Vth is the threshold voltage of the driving transistor. According to the above formula of the output current of the driving transistor, by bringing the gate voltage Vdata+Vth and the source voltage Vdd of the driving transistor in the pixel driving circuit of the present disclosure into the above formula, it may obtain that the output current of the driving transistor in the pixel driving circuit of the present disclosure is I=(μWCox/2L)(Vdata+Vth−Vdd−Vth)². The pixel driving circuit can avoid the affecting of the threshold of the driving transistor on the output current thereof.

It should be noted that in other exemplary embodiments, the first transistor T1 may also be a P-type transistor and the potentials at the reset signal terminal Re and the first enabling signal terminal may also be different.

Compared to the pixel driving circuit in the related art, the pixel driving circuit provided in the exemplary embodiment can realize the internal compensation of the pixel driving circuit with fewer transistors, so that the pixel driving circuit has a smaller layout area.

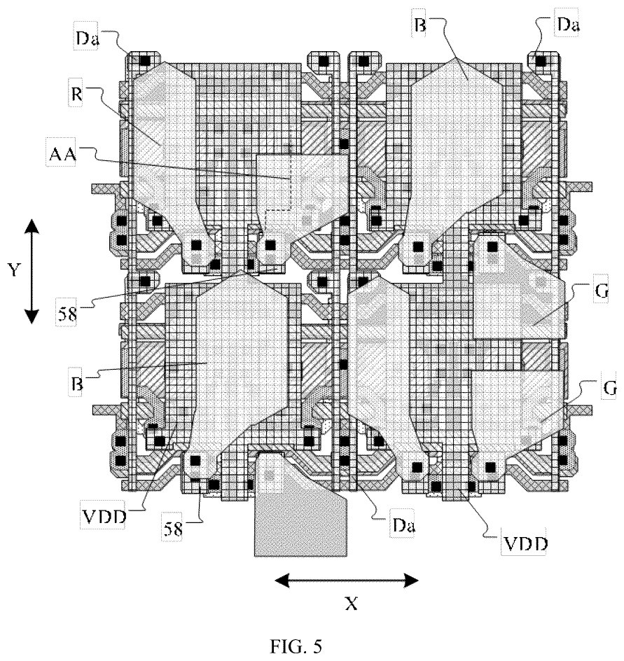

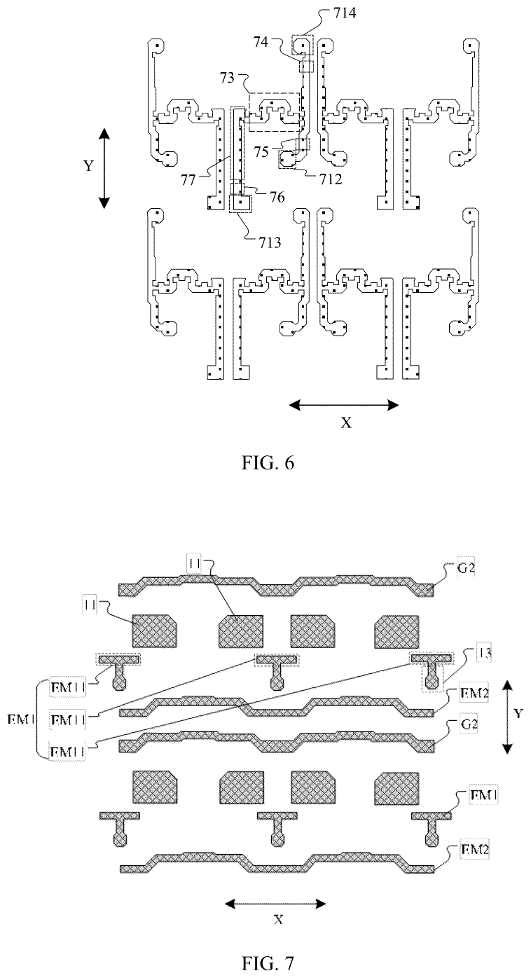

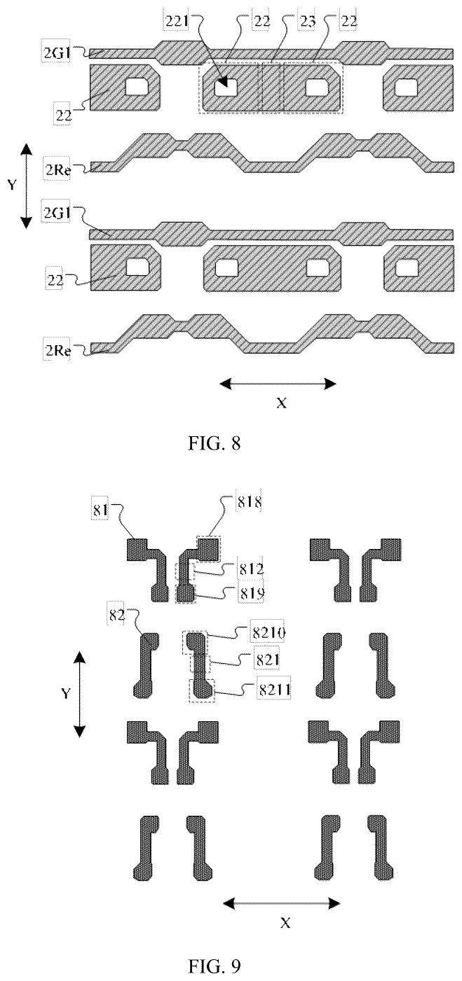

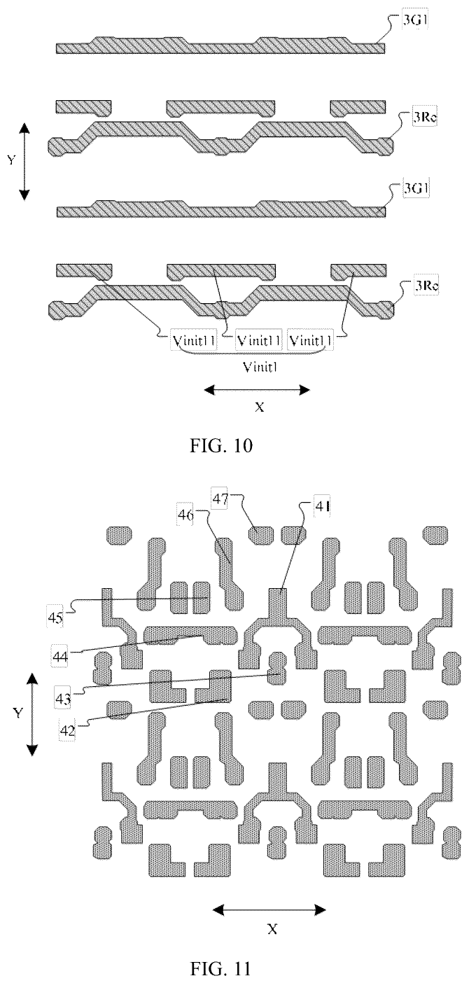

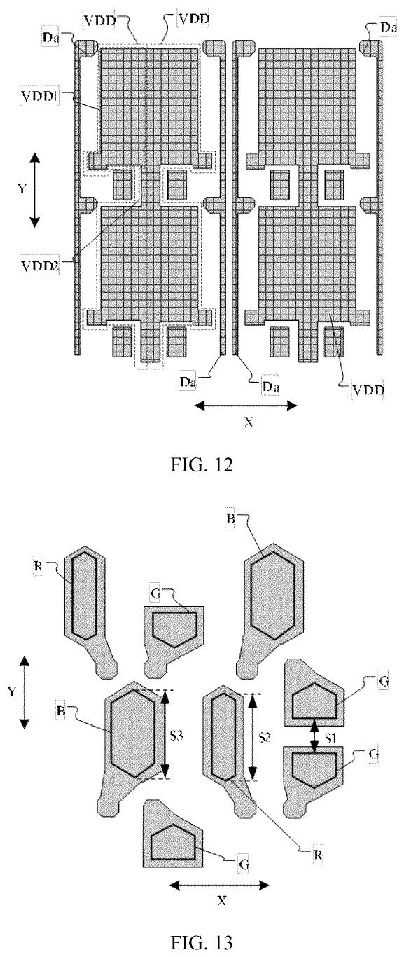

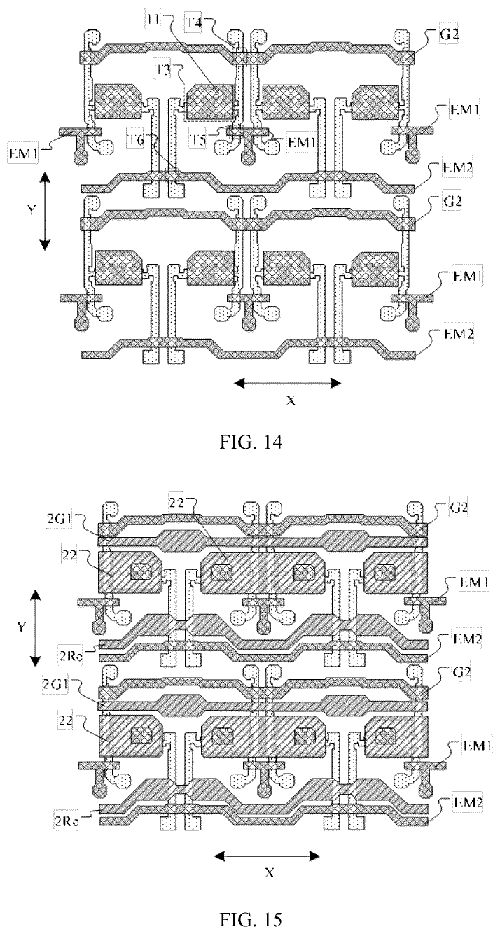

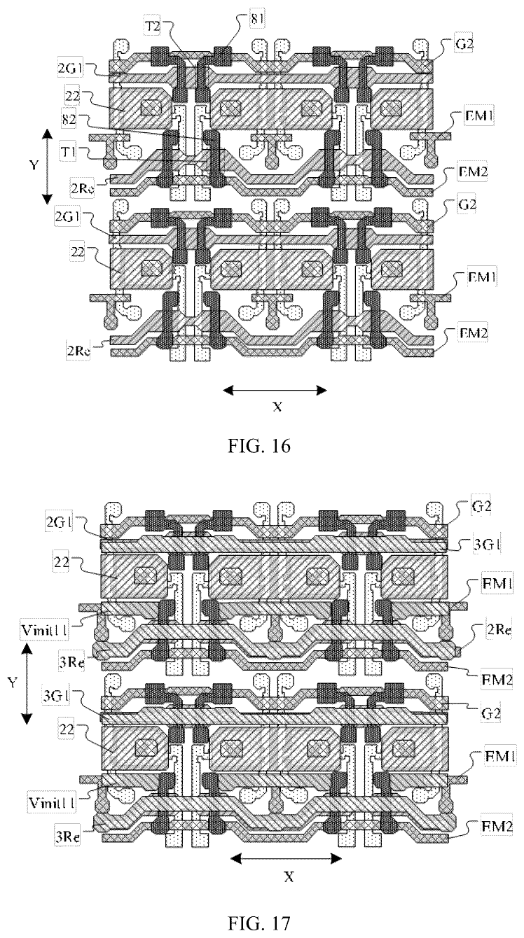

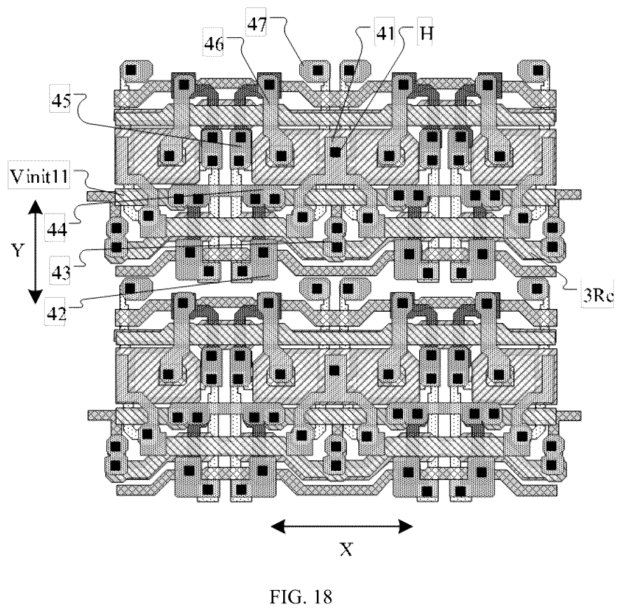

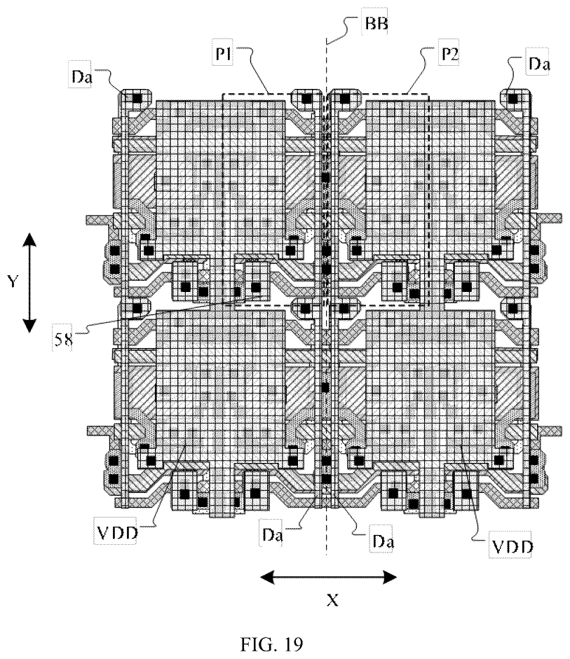

Further, an exemplary embodiment provides a display panel which may include the pixel driving circuit shown in FIG. 3. The display panel may include a base substrate, a first active layer, a first conductive layer, a second conductive layer, a second active layer, a third conductive layer, a fourth conductive layer, a fifth conductive layer, and an electrode layer provided in sequence in a stacked manner. An insulating layer may be provided between the above layers. As shown in FIGS. 5-19, FIG. 5 is a structure layout diagram of a display panel according to an exemplary embodiment of the present disclosure, FIG. 6 is a structure layout diagram of a first active layer in FIG. 5, FIG. 7 is a structure layout diagram of a first conductive layer in FIG. 5, FIG. 8 is a structure layout diagram of a second conductive layer in FIG. 5, FIG. 9 is a structure layout diagram of a second active layer in FIG. 5, FIG. 10 is a structure layout diagram of a third conductive layer in FIG. 5, FIG. 11 is a structure layout diagram of a fourth conductive layer in FIG. 5, FIG. 12 is a structure layout diagram of a fifth conductive layer in FIG. 5, FIG. 13 is a structure layout diagram of an electrode layer in FIG. 5, FIG. 14 is a structure layout diagram of the first active layer and the first conductive layer in FIG. 5, FIG. 15 is a structure layout diagram of the first active layer, the first conductive layer and the second conductive layer in FIG. 5, FIG. 16 is a structure layout diagram of the first active layer, the first conductive layer, the second conductive layer and the second active layer in FIG. 5, FIG. 17 is a structure layout diagram of the first active layer, the first conductive layer, the second conductive layer, the second active layer and the third conductive layer in FIG. 5, FIG. 18 is a structure layout diagram of the first active layer, the first conductive layer, the second conductive layer, the second active layer, the third conductive layer and the fourth conductive layer in FIG. 5, and FIG. 19 is a structure layout diagram of the first active layer, the first conductive layer, the second conductive layer, the second active layer, the third conductive layer, the fourth conductive layer and the fifth conductive layer in FIG. 5. The display panel may include a plurality of pixel driving circuits as shown in FIG. 1. As shown in FIG. 19, the plurality of pixel driving circuits may include a first pixel driving circuit P1 and a second pixel driving circuit P2 arranged adjacent to each other in a first direction X. The first pixel driving circuit P1 and the second pixel driving circuit P2 may be provided to be mirror-symmetrical with respect to a mirror-symmetrical plane BB. The mirror-symmetrical plane BB may be perpendicular to the base substrate. An orthographic projection of the first pixel driving circuit P1 on the base substrate and an orthographic projection of the second pixel driving circuit P2 on the base substrate are provided symmetrically by taking the intersecting line of the mirror-symmetrical plane BB with the base substrate as the symmetry axis. The first pixel driving circuit P1 and the second pixel driving circuit P2 may form a repetition unit, the display panel may include a plurality of repetition units arranged in an array in the first direction X and a second direction Y, where the first direction X may be a row direction and the second direction Y may be a column direction.

As shown in FIGS. 5, 6 and 14, the first active layer may include a third active part 73, a fourth active part 74, a fifth active part 75, a sixth active part 76, a seventh active part 77, a twelfth active part 712, a thirteenth active part 713 and a fourteenth active part 714. The third active part 73 may be used to form a channel region of the driving transistor T3; the fourth active part 74 may be used to form a channel region of the fourth transistor T4; the fifth active part 75 may be used to form a channel region of the fifth transistor T5; the sixth active part 76 may be used to form a channel region of the sixth transistor T6; the seventh active part 77 is connected between the third active part 73 and the sixth active part 76; the twelfth active part 712 is connected to an end of the fifth active part 75 away from the third active part 73; the thirteenth active part 713 is connected to an end of the sixth active part 76 away from the third active part 73; and the fourteenth active part 714 is connected to an end of the fourth active part 74 away from the third active part 73. The first active layer may be formed of polycrystalline silicon material, and accordingly, the driving transistor T3, the fourth transistor T4, the fifth transistor T5 and the sixth transistor T6 may be P-type low temperature polycrystalline silicon thin film transistors.

As shown in FIGS. 5, 7 and 14, the first conductive layer may include a first conductive part 11, a second gate line G2, a first enabling signal line EM1, and a second enabling signal line EM2. The first enabling signal line EM1 includes a plurality of enabling signal line sections EM11, and orthographic projections of the plurality of enabling signal line sections EM11 on the base substrate extend in the first direction X and are spaced apart in the first direction X. The second gate line G2 may be used to provide the second gate driving signal terminal in FIG. 3; the first enabling signal line EM1 may be used to provide the first enabling signal terminal in FIG. 3; and the second enabling signal line EM2 may be used to provide the second enabling signal terminal in FIG. 3. An orthographic projection of the second gate line G2 on the base substrate and an orthographic projection of the second enabling signal line EM2 on the base substrate may both extend along the first direction X. In the exemplary embodiment, an orthographic projection of a structure on the base substrate extends in a certain direction, which may be understood to mean that the orthographic projection of the structure on the base substrate extends in that direction in a straight line or in a bending line. The orthographic projection of the second gate line G2 on the base substrate covers the orthographic projection of the fourth active part 74 on the base substrate, and a part of the second gate line G2 is used to form the gate electrode of the fourth transistor. The orthographic projection of the enabling signal line section EM11 on the base substrate covers the orthographic projection of the fifth active part 75 on the base substrate, and a part of the enabling signal line section EM11 may be used to form the gate electrode of the fifth transistor T5. The orthographic projection of the enabling signal line section EM11 on the base substrate may cover both the orthographic projections of two fifth active parts 75 in the same repetition unit on the base substrate. Furthermore, an orthographic projection of the seventh active part 77 on the base substrate may extend in the second direction Y and through the gap between the orthographic projections of two adjacent enabling signal line sections EM11 in the first direction X on the base substrate. That is, the orthographic projection of the seventh active part 77 on the base substrate is located between the orthographic projections of the two adjacent enabling signal line sections EM11 on the base substrate, and the orthographic projection of the seventh active part 77 on the base substrate and the orthographic projections of the enabling signal line sections EM11 on the base substrate are not overlapped with each other. An orthographic projection of the second enabling signal line EM2 on the base substrate covers an orthographic projection of the sixth active part 76 on the base substrate, and a part of the second enabling signal line EM2 may be used to form the gate electrode of the sixth transistor. An orthographic projection of the first conductive part 11 on the base substrate covers an orthographic projection of the third active part 73 on the base substrate, and the first conductive part 11 may be used to form the gate electrode of the driving transistor T3 and the first electrode of the capacitor C. As shown in FIG. 14, in the same pixel driving circuit, the orthographic projection of the first conductive part 11 on the base substrate may be located between the orthographic projection of the second gate line G2 on the base substrate and the orthographic projection of the first enabling signal line EM1 on the base substrate, and the orthographic projection of the second enabling signal line EM2 on the base substrate may be located at a side of the orthographic projection of the first enabling signal line EM1 on the base substrate away from the orthographic projection of the first conductive part 11 on the base substrate. Further, in the display panel, a conducting treatment may be performed on the first active layer by using the first conductive layer as a mask, i.e., a region of the first active layer covered by the first conductive layer may form a channel region of the transistor, and a region of the first active layer not covered by the first conductive layer forms a conductor structure. In the exemplary embodiment, the first enabling signal line is provided as the enabling signal line sections EM11 that are spaced apart from each other in the first direction, thereby avoiding the intersection of the first enabling signal line with the seventh active part 77, and in the display panel, the second electrode of the third transistor and the first electrode of the sixth transistor may be directly connected by using the seventh active part 77, which arrangement may reduce the connection path between the third transistor and the sixth transistor. Furthermore, this arrangement may avoid connecting the third transistor and the seventh transistor via an additional bridge part, thus effectively reducing the layout area of the pixel driving circuit. It should be noted that in other pixel driving circuits, the layout arrangement of the driving transistor, the fifth transistor and the sixth transistor in the display panel may be achieved by using the above structure as long as the fifth transistor and the sixth transistor have different gate lines.

As shown in FIGS. 5, 8 and 15, the second conductive layer may include a third gate line 2G1, a second reset signal line 2Re, and a plurality of second conductive parts 22. The third gate line 2G1 may be used to provide the first gate driving signal terminal in FIG. 3, and the second reset signal line 2Re may be used to provide the reset signal terminal in FIG. 3. An orthographic projection of the third gate line 2G1 on the base substrate and an orthographic projection of the second reset signal line 2Re on the base substrate may both extend along the first direction X. As shown in FIG. 8, the second conductive layer may further include a plurality of first connection parts 23, and in the same repetition unit, the first connection part 23 may be connected between two adjacent second conductive parts 22 in the row direction. In addition, in other exemplary embodiments, the adjacent second conductive parts 22 may also be connected to each other in adjacent repetition units in the row direction.

As shown in FIGS. 5, 9 and 16, the second active layer may include active parts 81 and 82 which are provided independently. The active part 81 may include a second active part 812 and an eighth active part 818 and a ninth active part 819 connected to two ends of the second active part 812. The active part 82 may include a first active part 821 and a tenth active part 8210 and an eleventh active part 8211 connected to two ends of the first active part 821. The first active part 821 may be used to form a channel region of the first transistor T1, and the second active part 812 may be used to form a channel region of the second transistor T2. The second active layer may be formed of indium gallium zinc oxide, and accordingly, the first transistor T1 and the second transistor T2 may be N-type metal oxide thin film transistors. The orthographic projection of the second reset signal line 2Re on the base substrate may cover an orthographic projection of the first active part 821 on the base substrate, a part of the second reset signal line 2Re may be used to form a bottom gate of the first transistor, the orthographic projection of the third gate line 2G1 on the base substrate may cover an orthographic projection of the second active part 812 on the base substrate, and a part of the third gate line 2G1 may be used to form ae bottom gate of the second transistor T2. Furthermore, in the first direction X, the orthographic projection of the first active part 821 on the base substrate may be located between the orthographic projection of the sixth active part 76 on the base substrate and the orthographic projection of the fifth active part 75 on the base substrate.

As shown in FIGS. 5, 10, 17, the third conductive layer may include a first gate line 3G1, a first reset signal line 3Re, and an initial signal line Vinit1. An orthographic projection of the first gate line 3G1 on the base substrate, an orthographic projection of the initial signal line Vinit1 on the base substrate, and an orthographic projection of the first reset signal line 3Re on the base substrate may all extend in the first direction X. The first gate line 3G1 may be used to provide the first gate driving signal terminal in FIG. 3, the orthographic projection of the first gate line 3G1 on the base substrate may cover the orthographic projection of the second active part 812 on the base substrate, a part of the first gate line 3G1 may be used to form a top gate of the second transistor T2, and the first gate line 3G1 may be connected to the third gate line 2G1 through a vial hole located in a wiring area along the edge of the display panel. The first reset signal line 3Re is used to provide the reset signal terminal in FIG. 3, an orthographic projection of the first reset signal line 3Re on the base substrate may cover the orthographic projection of the first active part 821 on the base substrate, a part of the first reset signal line 3Re may be used to form a top gate of the first transistor, and the first reset signal line 3Re may be connected to the second reset signal line 2 through a via hole located in the wiring area along the edge of the display panel. The initial signal line Vinit1 may include a plurality of initial signal line sections Vinit11, and orthographic projections of the plurality of initial signal line sections Vinit11 on the base substrate may extend in the first direction and be spaced apart in the first direction. The orthographic projection of the tenth active part 8210 on the base substrate is located in the gap between the orthographic projections of the two adjacent initial signal line sections Vinit11 in the first direction X on the base substrate. That is, the region covered by the orthographic projection of the tenth active part 8210 on the base substrate moving infinitely in the first direction and the orthographic projections of the two initial signal line sections Vinit11 adjacent thereto on the base substrate intersect. Furthermore, the orthographic projection of the seventh active part 77 on the base substrate passes through the gap between the orthographic projections of the adjacent initial signal line sections Vinit11 in the first direction X on the base substrate. Furthermore, the orthographic projection of the initial signal line section Vinit11 on the base substrate may at least partially overlap with the orthographic projection of the enabling signal line section EM11 on the base substrate, which arrangement may reduce the layout space occupied by the initial signal line Vinit1 and thus reduce the layout area of the pixel driving circuit. As shown in FIGS. 5 and 17, in the same pixel driving circuit, the orthographic projection of the first gate line 3G1 on the base substrate is located between the orthographic projection of the second gate line G2 on the base substrate and the orthographic projection of the first conductive part on the base substrate, and the orthographic projection of the first reset signal line 3Re on the base substrate is located between the orthographic projection of the first enabling signal line EM1 on the base substrate and the orthographic projection of the second enabling signal line EM2 on the base substrate. Furthermore, the orthographic projection of the third gate line 2G1 on the base substrate may be located between the orthographic projection of the second gate line G2 on the base substrate and the orthographic projection of the first conductive part on the base substrate; and the orthographic projection of the second reset signal line 2Re on the base substrate may be located between the orthographic projection of the first enabling signal line EM1 on the base substrate and the orthographic projection of the second enabling signal line EM2 on the base substrate. Furthermore, in the display panel, a conducting treatment may be performed on the second active layer by using the third conductive layer as a mask, i.e. the region of the second active layer covered by the third conductive layer may form the channel region of the transistor and the region of the second active layer not covered by the third conductive layer forms a conductor structure.

As shown in FIGS. 5, 11 and 18, the fourth conductive layer may include a first bridge part 41, a second bridge part 42, a third bridge part 43, a fourth bridge part 44, a fifth bridge part 45, a sixth bridge part 46 and a seventh bridge part 47. The first bridge part 41 may be connected to the first connection part 23 via a via hole H and to the twelfth active part 712 via a via hole to connect the first electrode of the fifth transistor and the second electrode of the capacitor C. In the same repetition unit, the two pixel driving circuits may share the same first bridge part 41, and the first bridge part 41 may be mirror-symmetrical with respect to the mirror-symmetrical plane BB of the first pixel driving circuit P1 and the second pixel driving circuit P2. At the same time, an orthographic projection of the first bridge part 41 on the base substrate may be provided symmetrically by taking the intersecting line of the mirror-symmetrical plane BB with the base substrate as the symmetry axis. It should be noted that in the exemplary embodiment, black squares indicate locations of the via holes, and only some of the via holes are indicated. The second bridge part 42 may be connected to the thirteenth active part 713 and the eleventh active part 8211 respectively through via holes to connect the second electrode of the sixth transistor T6 and the second electrode of the first transistor T1. As shown in FIG. 7, the first conductive layer may further include a plurality of projections 13 provided and connected in one-to-one correspondence with the enabling signal line sections EM1, and an orthographic projection of the projection 13 on the base substrate is provided at a side of the orthographic projection of a corresponding enabling signal line section EM1 thereto on the base substrate away from the first conductive part 11. The third bridge part 43 may be connected to the projection 13 and the first reset signal line 3Re respectively through via holes, which arrangement allows the first enabling signal terminal and the reset signal terminal in FIG. 3 to be equipotential without the arrangement of additional signal lines. It should be understood that in other exemplary embodiments, the plurality of enabling signal line sections EM1 spaced part in the first direction may also be connected to a same other control signal line. An orthographic projection of the fourth bridge part 44 on the base substrate extends in the first direction X. The fourth bridge part 44 is connected to two adjacent initial signal line sections Vinit11 in the first direction through via holes. The fourth bridge part 44 is connected, through a via hole, to the tenth active part 8210 located between the two adjacent initial signal line sections Vinit11. The fourth bridge part 44 may connect the first electrode of the first transistor and the initial signal terminal in FIG. 3, and may connect the plurality of initial signal line sections Vinit11 arranged in the first direction X to be an integral initial signal line. The fifth bridge part 45 is connected to the seventh active part 77 and the ninth active part 819 respectively through via holes to connect the second electrode of the second transistor and the second electrode of the driving transistor. The sixth bridge part 46 may be connected to the first conductive part 11 and the eighth active part 818 respectively through via holes to connect the first electrode of the second transistor T2 and the gate electrode of the driving transistor. As shown in FIG. 8, an opening 221 is formed in the second conductive part 22, and an orthographic projection, on the base substrate, of a via hole connected between the first conductive part 11 and the sixth bridge part 46 is located within an orthographic projection of the opening 221 on the base substrate, so as to insulate the conductive structure in the via hole with the second conductive part 22. The seventh bridge part 47 may be connected to the fourteenth active part 714 through a via hole to be connected to the first electrode of the fourth transistor.

As shown in FIGS. 5, 12 and 19, the fifth conductive layer may include a plurality of power lines VDD, a plurality of data lines Da, and an eighth bridge part 58. An orthographic projection of the power line VDD on the base substrate and an orthographic projection of the data line Da on the base substrate may both extend along the second direction Y. The power line VDD may be used to provide the first power supply terminal in FIG. 3, and the data line Da may be used to provide the data signal terminal in FIG. 3. As shown in FIGS. 5 and 19, each column of the pixel driving circuits may be provided with one power line correspondingly, the power line VDD in the first pixel driving circuit P1 may be connected to the first bridge part 41 through a via hole, and the power line VDD in the second pixel driving circuit P2 may be connected to the same first bridge part 41 through a via hole, thereby connecting the first electrode of the fifth transistor to the first power supply terminal. The data line Da may be connected to the seventh bridge part 47 through a via hole to connect the first electrode of the fourth transistor and the data signal terminal. The eighth bridge part 58 may be connected to the second bridge part 42 through a via hole to connect to the second electrode of the sixth transistor T6. The power line VDD may include a first extension part VDD1 and a second extension part VDD2. A dimension, in the first direction X, of an orthographic projection of the first extension part VDD1 on the base substrate is larger than a dimension, in the first direction X, of an orthographic projection of the second extension part VDD2 on the base substrate, and the orthographic projection of the first extension part VDD1 on the base substrate covers an orthographic projection of the first active part 821 on the base substrate and an orthographic projection of the second active part 812 on the base substrate. The power line VDD may reduce the influence of light on the characteristics of the first transistor T1 and the second transistor T2. In two adjacent repetition units in the row direction, the power lines VDD in two adjacent pixel driving circuits may be connected to each other, so that the power lines VDD and the second conductive part 22 may form a grid structure, and the power lines with such grid structure may reduce the voltage drop of the power supply signal thereon.

As shown in FIGS. 5 and 13, the electrode layer may include a plurality of electrode parts, and the electrode part may be used to form the first electrode of the light emitting unit. The plurality of electrode parts includes a plurality of R electrode parts R, a plurality of G electrode parts G, a plurality of B electrode parts B. In a plurality of electrode parts connected to a same row of the pixel driving circuits, the R electrode part, the G electrode part, the B electrode part, the G electrode part are arranged in a row direction in that order. In two adjacent columns of the pixel driving circuits, a plurality of R electrode parts and a plurality of B electrode parts are connected to a same column of the pixel driving circuits, the R electrode part and the B electrode part connected to the same column of the pixel driving circuits are arranged in a column direction in that order, and a plurality of G electrode parts are connected to another column of the pixel driving circuits. A minimum distance S1, in the column direction, between orthographic projections, on the base substrate, of two G electrode parts connected to adjacent rows of the pixel driving circuits and connected to a same column of the pixel driving circuits is less than a dimension S2, in the column direction, of an orthographic projection of the R electrode part on the base substrate or a dimension S3, in the column direction, of the orthographic projection of the B electrode part on the base substrate. The display panel may further include a pixel definition layer provided on a side of the electrode layer away from the base substrate. The orthographic projection of the R electrode part on the base substrate is coincided with an orthographic projection of a corresponding opening in the pixel definition layer on the base substrate. The orthographic projection of the G electrode part on the base substrate is coincided with an orthographic projection of a corresponding opening in the pixel definition layer on the base substrate. The orthographic projection of the B electrode part on the base substrate is coincided with an orthographic projection of a corresponding opening in the pixel definition layer on the base substrate. Each electrode part may be connected to the eighth bridge part 58 through a via hole to connect to the second electrode of the sixth transistor.

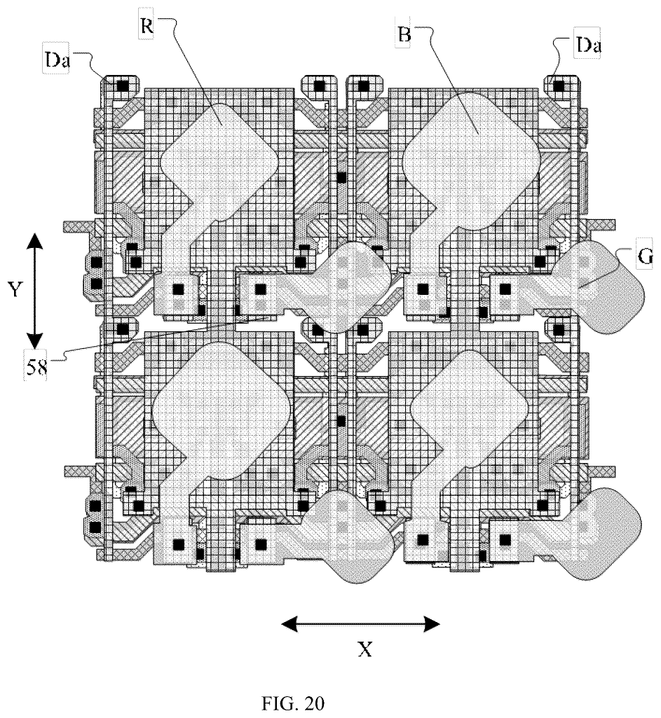

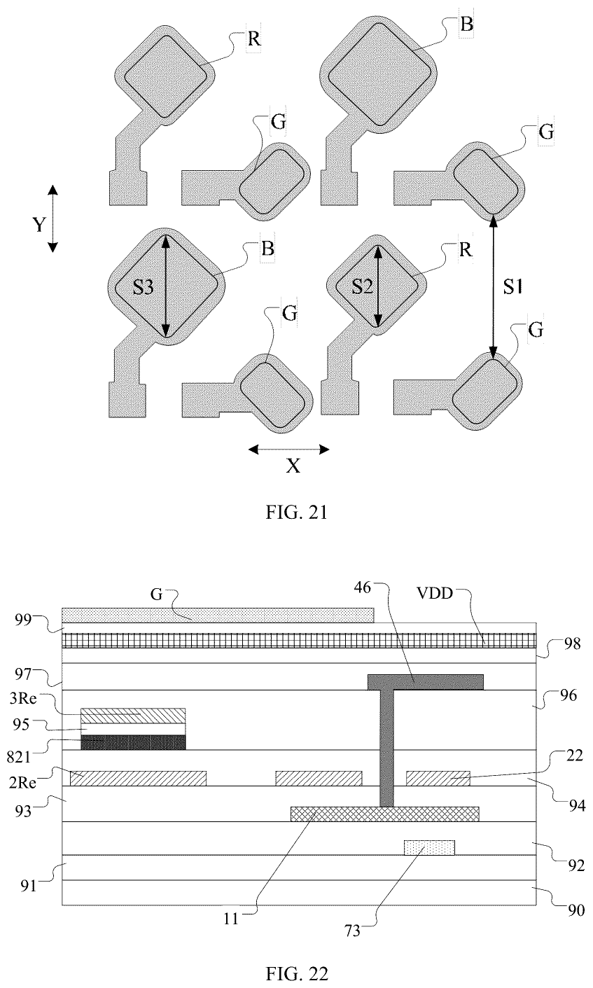

As shown in FIGS. 20 and 21, FIG. 20 is a structure layout diagram of a display panel according to another exemplary embodiment of the present disclosure, and FIG. 21 is a structure layout diagram of an electrode layer in FIG. 20. The display panel shown in FIG. 20 differs from the display panel shown in FIG. 5 only in the structure of the electrode layer. As shown in FIGS. 20 and 21, the electrode layer may include a plurality of electrode parts: R electrode part R, G electrode part G, B electrode part B. Each electrode part may be connected to the eighth bridge part 58 through a via hole to connect to the second electrode of the sixth transistor. In a plurality of electrode parts connected to a same row of the pixel driving circuits, the R electrode part, the G electrode part, the B electrode part, the G electrode part are arranged in a row direction in that order. In two adjacent columns of the pixel driving circuits, a plurality of R electrode parts and a plurality of B electrode parts are connected to a same column of the pixel driving circuits, the R electrode part and the B electrode part connected to the same column of the pixel driving circuits are arranged in a column direction in that order, and a plurality of G electrode parts are connected to another column of the pixel driving circuits. A minimum distance S1, in the column direction, between orthographic projections, on the base substrate, of two G electrode parts connected to adjacent rows of the pixel driving circuits and connected to a same column of the pixel driving circuits is greater than a dimension S2, in the column direction, of an orthographic projection of the R electrode part on the base substrate or a dimension S3, in the column direction, of the orthographic projection of the B electrode part on the base substrate. The orthographic projection of the R electrode part on the base substrate is coincided with an orthographic projection of a corresponding opening in the pixel definition layer on the base substrate. The orthographic projection of the G electrode part on the base substrate is coincided with an orthographic projection of a corresponding opening in the pixel definition layer on the base substrate. The orthographic projection of the B electrode part on the base substrate is coincided with an orthographic projection of a corresponding opening in the pixel definition layer on the base substrate.

It should be noted that the repetition unit is illustrated by the pixel driving circuit as an example, i.e., the pixel driving circuits in the different repetition units in the display panel are the same in structure. The electrode part in the display panel is not included in the pixel driving circuit. As shown in FIGS. 5, 18, 19 and 20, the black square drawn on a side of the fourth conductive layer away from the base substrate indicate a via hole connecting the fourth conductive layer to other layers at a side of the fourth conductive layer facing the base substrate; the black square drawn on a side of the fifth conductive layer away from the base substrate indicates a via hole connecting the fifth conductive layer to other layers at a side of the fifth conductive layer facing the base substrate; and the black square drawn on a side of the electrode layer away from the base substrate indicates a via hole connecting the electrode layer to other layers at a side of the electrode layer facing the base substrate. The black square only indicates a location of the via hole, and the different via holes indicated by the black squares at different locations can pass through different insulation layers.

FIG. 22 is a partial section view of a display panel taken along a dotted line AA in FIG. 5. The display panel may further include a first insulating layer 91, a second insulating layer 92, a third insulating layer 93, a fourth insulating layer 94, a fifth insulating layer 95, a first dielectric layer 96, a passivation layer 97, a first planarization layer 98, a second planarization layer 99. The base substrate 90, the first insulating layer 91, the first active layer, the second insulating layer 92, the first conductive layer, the third insulating layer 93, the second conductive layer, the fourth insulating layer 94, the second active layer, the fifth insulating layer 95, the third conductive layer, the first dielectric layer 96, the fourth conductive layer, the passivation layer 97, the first planarization layer 98, the fifth conductive layer, the second planarization layer 99, and the electrode layer are stacked sequentially. The first insulating layer 91, the second insulating layer 92, the third insulating layer 93, the fourth insulating layer 94, the fifth insulating layer 95 may be a single-layer structure or a multi-layer structure, and the material of the first insulating layer 91, the second insulating layer 92, the third insulating layer 93, the fourth insulating layer 94, the fifth insulating layer 95 may be at least one of silicon nitride, silicon oxide, silicon nitride; the first dielectric layer 96 may be a silicon nitride layer; the material of the passivation layer 97 may include an organic insulating material or an inorganic insulating material, e.g., a silicon nitride material; the material of the first planarization layer 98 and the second planarization layer 99 may be an organic material, e.g., a material such as polyimide (PI), polyethylene terephthalate (PET), polyethylene naphthalate (PEN), silicon-on-glass bonding structure (SOG). The base substrate 90 may include a glass substrate, a barrier layer, and a polyimide layer stacked sequentially, and the barrier layer may be an inorganic material. The material of the first conductive layer, the second conductive layer and the third conductive layer may be one of molybdenum, aluminium, copper, titanium, niobium or an alloy thereof, or a molybdenum/titanium alloy or laminated layer, or the like. The material of the fourth conductive layer and the fifth conductive layer may include a metallic material, for example one of molybdenum, aluminium, copper, titanium, niobium or an alloy thereof, or a molybdenum/titanium alloy or laminated structure, or a titanium/aluminium/titanium laminated structure. The electrode layer may include an indium gallium zinc oxide layer.

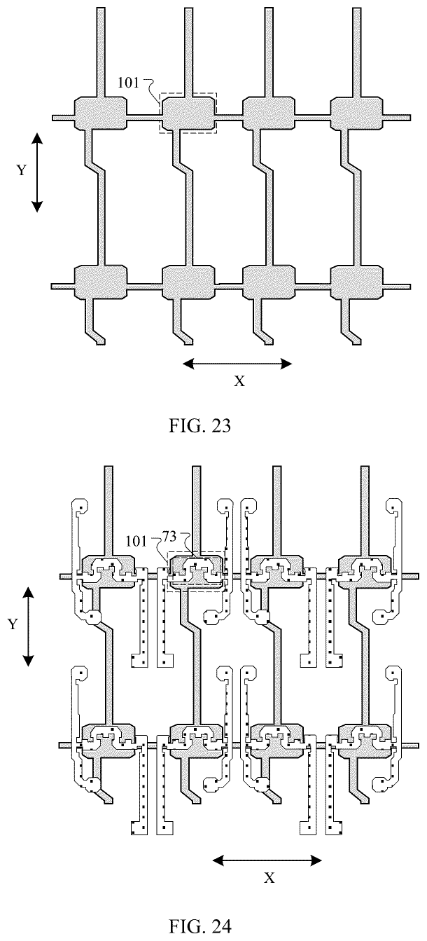

In other exemplary embodiments, the display panel shown in FIG. 5 may further include a light shielding layer, which may be provided between the base substrate and the first active layer. FIG. 23 is a structure layout diagram of a light shielding layer of a display panel according to another exemplary embodiment of the present disclosure. The light shielding layer may include a plurality of light shielding parts 101 arranged in the first direction X and the second direction Y, and adjacent light shielding parts 101 may be connected to each other. The light shielding layer may be a conductor structure, for example, the light shielding layer may be a light shielding metal layer.

FIG. 24 is a structure layout diagram of a light shielding layer and a first active layer of a display panel according to another exemplary embodiment of the present disclosure. The orthographic projection of the light shielding part 101 on the base substrate may cover the orthographic projection of the third active part 73 on the base substrate, and the light shielding part 101 may reduce the affecting of light on the characteristics of the driving transistor.

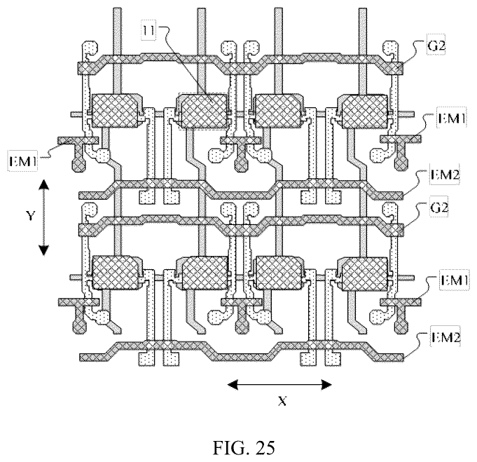

FIG. 25 is a structure layout diagram of a light shielding layer, a first active layer and a first conductive layer of a display panel according to another exemplary embodiment of the present disclosure. The orthographic projection of the light shielding part 101 on the base substrate may be overlapped with the orthographic projection of the first conductive part 11 on the base substrate, and the light shielding layer may be connected to a stable power supply terminal, e.g., the light shielding layer may be connected to the first power supply terminal, the initial signal terminal and the like in FIG. 3. The light shielding part 101 may stabilize the voltage of the first conductive part 11, thereby reducing the voltage fluctuation of the gate electrode of the driving transistor T3 during the light emitting phase.

It should be noted that the scale of the accompanying drawings in the present disclosure may be used as a reference in the actual process which but is not limited thereto, e.g., a width to length ratio of the channel, thicknesses of respective film layers and intervals therebetween, and widths of respective signal lines and intervals therebetween may be adjusted according to actual needs. The number of pixels in the display substrate and the number of sub-pixels in each pixel are also not limited to the number shown in the figures, and the accompanying drawings depicted in the present disclosure are only structural diagrams. Furthermore, terms such as first and second are used only to define names of different structures, which have no definition on a particular order.

An exemplary embodiment also provides a display device including the display panel described above. The display device may be a display device such as a mobile phone, a tablet computer, a television.

A person skilled in the art may easily conceive of other embodiments of the present disclosure after considering the specification and practicing what is disclosed herein. The present application is intended to cover any variations, uses or adaptations of the present disclosure that follow the general principle of the present disclosure and include the common knowledge and the conventional technical means in the art that are not disclosed herein. The description and embodiments are considered to be exemplary only and the true scope and spirit of the present disclosure is indicated by the claims.

It should be understood that the present disclosure is not limited to the precise construction already described above and illustrated in the accompanying drawings, and that various modifications and changes may be made without departing from the scope thereof. The scope of the present disclosure is limited only by the appended claims.

1. A display panel, comprising a light emitting unit and a pixel driving circuit for driving the light emitting unit, wherein the pixel driving circuit comprises:
a driving transistor;
a fifth transistor, comprising a first electrode connected to a power line, a second electrode connected to a first electrode of the driving transistor and a gate electrode connected to a first enabling signal line; and
a sixth transistor, comprising a first electrode connected to a second electrode of the driving transistor, a second electrode connected to a first electrode of the light emitting unit and a gate electrode connected to a second enabling signal line,
the display panel further comprises:
a base substrate;
a first active layer, provided on a side of the base substrate, the first active layer comprising a third active part, a fifth active part, a sixth active part, the third active part being configured to form a channel region of the driving transistor, the fifth active part being configured to form a channel region of the fifth transistor, and the sixth active part being configured to form a channel region of the sixth transistor; and
a first conductive layer, provided on a side, away from the base substrate, of the first active layer, wherein the first conductive layer comprises:
the first enabling signal line, an orthographic projection of the first enabling signal line on the base substrate extending in a first direction and covering an orthographic projection of the fifth active part on the base substrate, and a part of the first enabling signal line being configured to form the gate electrode of the fifth transistor;
the second enabling signal line, an orthographic projection of the second enabling signal line on the base substrate extending in the first direction and covering an orthographic projection of the sixth active part on the base substrate, and a part of the second enabling signal line being configured to form a gate electrode of the sixth transistor; and
a first conductive part, an orthographic projection of the first conductive part on the base substrate covering the third active part, and the first conductive part being configured to form the gate electrode of the driving transistor.

2. The display panel according to claim 1, wherein the first active layer further comprises:
a seventh active part, connected between the third active part and the sixth active part, an orthographic projection of the seventh active part on the base substrate extending in a second direction, and the second direction intersecting the first direction,
the first enabling signal line comprises a plurality of enabling signal line sections, orthographic projections of the plurality of enabling signal line sections on the base substrate are spaced apart in the first direction and extend in the first direction,
the orthographic projection of the seventh active part on the base substrate passes through a gap between orthographic projections, on the base substrate, of two of the enabling signal line sections adjacent in the first direction,
the display panel further comprises:
a first control signal line, an orthographic projection of the first control signal line on the base substrate extending in the first direction, and the plurality of enabling signal line sections spaced part in the first direction being connected to a same first control signal line.

3. The display panel according to claim 2, wherein the fifth transistor is a P-type transistor, the pixel driving circuit further comprises a first transistor of type N comprising a first electrode connected to an initial signal line, a second electrode connected to the first electrode of the light emitting unit, a gate electrode connected to a first reset signal line, and the first control signal line is reused as the first reset signal line,
the display panel further comprises:
a second active layer, provided on a side, away from the base substrate, of the first conductive layer and comprising a first active part for forming a channel region of the first transistor; and
a third conductive layer, provided on a side, away from the base substrate, of the second active layer and comprising the first reset signal line, an orthographic projection of the first reset signal line on the base substrate covering the orthographic projection of the first active part on the base substrate, and a part of the first reset signal line being configured to form a top gate electrode of the first transistor.

4. The display panel according to claim 3, wherein the first conductive layer further comprises a plurality of projections provided and connected in one-to-one correspondence with the plurality of enabling signal line sections,
wherein an orthographic projection of the projection on the base substrate is provided between the orthographic projection of the enabling signal line section on the base substrate and the orthographic projection of the first reset signal line on the base substrate,
the display panel further comprises:
a fourth conductive layer, provided on a side, away from the base substrate, of the third conductive layer and comprising a third bridge part, the third bridge part being connected to the projection and the first reset signal line respectively through via holes.

5. The display panel according to claim 3, wherein the orthographic projection of the second enabling signal line on the base substrate does not overlap with the orthographic projection of the first enabling signal line on the base substrate, and
the orthographic projection of the first active part on the base substrate is provided between the orthographic projection of the second enabling signal line on the base substrate and the orthographic projection of the first enabling signal line on the base substrate.

6. The display panel according to claim 3, wherein in the first direction, the orthographic projection of the first active part on the base substrate is provided between an orthographic projection of the sixth active part on the base substrate and the orthographic projection of the fifth active part on the base substrate.

7. The display panel according to claim 2, wherein the first direction is a row direction, the second direction is a column direction, the display panel comprises a plurality of repetition units arranged in the row direction and the column direction, the repetition units each comprises two pixel driving circuits, the two pixel driving circuits comprise a first pixel driving circuit and a second pixel driving circuit arranged in the row direction, and the first pixel driving circuit and the second pixel driving circuit are provided in mirror symmetry;
the plurality of enabling signal line sections are provided in correspondence with the plurality of repetition units, the orthographic projection of the enabling signal line section on the base substrate covers the orthographic projections, on the base substrate, of two fifth active parts of a corresponding repetition unit.

8. The display panel according to claim 3, wherein the third conductive layer further comprises:
the initial signal line, comprising a plurality of initial signal line sections, orthographic projections of the plurality of initial signal line sections on the base substrate being spaced apart in the first direction and extending in the first direction;
the second active layer further comprises:
a tenth active part, connected to the first active part, an orthographic projection of at least part of the tenth active part on the base substrate being provided at a gap between orthographic projections, on the base substrate, of two of the initial signal line sections adjacent in the first direction,
the display panel further comprises:
a fourth conductive layer, provided on a side, away from the base substrate, of the third conductive layer and comprising a fourth bridge part, an orthographic projection of the fourth bridge part on the base substrate extending along the first direction, the fourth bridge part being connected to two of the initial signal line sections adjacent in the first direction through via holes respectively and being connected to the tenth active part provided between the two of the initial signal line sections adjacent in the first direction through a vial hole.

9. The display panel according to claim 8, wherein the orthographic projection of the initial signal line section on the base substrate is provided between the orthographic projection of the first conductive part on the base substrate and the orthographic projection of the first reset signal line on the base substrate,
the plurality of initial signal line sections are provided in correspondence with the plurality of enabling signal line sections, and the orthographic projection of the initial signal line section on the base substrate is at least partially overlapped with the orthographic projection of a corresponding enabling signal line section on the base substrate.

10. The display panel according to claim 1, wherein the pixel driving circuit further comprises:
a fourth transistor, comprising a first electrode connected to a data line, a second electrode connected to the first electrode of the driving transistor and a gate electrode connected to a second gate line,
the first active layer further comprises:
a fourth active part, configured to form a channel region of the fourth transistor,
the first conductive layer further comprises:
the second gate line, an orthographic projection of the second gate line on the base substrate extending in the first direction and covering an orthographic projection of the fourth active part on the base substrate, and a part of the second gate line being configured to form the gate electrode of the fourth transistor,
wherein the orthographic projection of the second gate line on the base substrate is provided at a side, away from the orthographic projection of the first enabling signal line on the base substrate, of the orthographic projection of the first conductive part on the base substrate.

11. The display panel according to claim 10, wherein the pixel driving circuit further comprises:
a second transistor, comprising a first electrode connected to the gate electrode of the driving transistor, a second electrode connected to the second electrode of the driving transistor and a gate electrode connected to a first gate line,
the display panel further comprises:
a second active layer, provided on a side, away from the base substrate, of the first conductive layer, and comprising a second active part configured to form a channel region of the second transistor; and
a third conductive layer, provided on a side, away from the base substrate, of the second active layer, and comprising the first gate line, an orthographic projection of the first gate line on the base substrate extending in the first direction and covering an orthographic projection of the second active part on the base substrate, and a part of the first gate line being configured to form a top gate of the second transistor,
wherein the orthographic projection of the first gate line on the base substrate is provided between the orthographic projection of the second gate line on the base substrate and the orthographic projection of the first conductive part on the base substrate.

12. The display panel according to claim 1, wherein the pixel driving circuit further comprises:
a first transistor, comprising a first electrode connected to an initial signal line, a second electrode connected to the first electrode of the light emitting unit and a gate electrode connected to a first reset signal line;
a second transistor, comprising a first electrode connected to the gate electrode of the driving transistor, a second electrode connected to the second electrode of the driving transistor, and a gate electrode connected to a first gate line;
a fourth transistor, comprising a first electrode connected to a data line, a second electrode connected to the first electrode of the driving transistor and a gate electrode connected to a second gate line; and
a capacitor, comprising a first electrode connected to the gate electrode of the driving transistor and a second electrode connected to the power line,
wherein the first transistor and the second transistor are N-type transistors and the driving transistor, the fourth transistor, the fifth transistor and the sixth transistor are P-type transistors.

13. The display panel according to claim 1, wherein the first direction is a row direction, the display panel comprises a plurality of repetition units arranged in the row direction and a column direction, the repetition units each comprises two pixel driving circuits, the two pixel driving circuits comprise a first pixel driving circuit and a second pixel driving circuit arranged in the row direction, and the first pixel driving circuit and the second pixel driving circuit are provided in mirror symmetry,
the pixel driving circuit further comprises a capacitor comprising a first electrode connected to the gate electrode of the driving transistor and a second electrode connected to the power line,
the display panel further comprises:
a second conductive layer, provided on a side, away from the base substrate, of the first conductive layer and comprising a second conductive part, an orthographic projection of the second conductive part on the base substrate being at least partially overlapped with the orthographic projection of the first conductive part on the base substrate, and the second conductive part being configured to form the second electrode of the capacitor; and
a fifth conductive layer, provided on a side, away from the base substrate, of the second conductive layer and comprising the power line, an orthographic projection of the power line on the base substrate extending in a second direction, and the second direction intersecting the first direction,
wherein in a same repetition unit, the second conductive part in the first pixel driving circuit is connected to the second conductive part in the second pixel driving circuit, and
each column of the pixel driving circuits corresponds to one power line, and in the repetition units adjacent in the row direction, adjacent power lines are connected to each other.

14. The display panel according to claim 13, wherein the second conductive layer further comprises a first connection part, and in the same repetition unit, adjacent second conductive parts are connected by the first connection part,
the first active layer further comprises a twelfth active part connected to an end, away from the third active part, of the fifth active part,
the display panel further comprises a fourth conductive layer provided between the second conductive layer and the fifth conductive layer, the fourth conductive layer further comprises a plurality of first bridge parts, the plurality of first bridge parts are provided in correspondence with the plurality of the repetition units, the first bridge part is connected to the first connection part and two twelfth active parts in the same repetition unit respectively through via holes and is connected to the power line through a via hole.

15. The display panel according to claim 14, wherein the first bridge part is mirror-symmetrical with respect to a mirror-symmetrical plane of the first pixel driving circuit and the second pixel driving circuit.

16. The display panel according to claim 1, wherein the pixel driving circuit further comprises:
a first transistor, comprising a first electrode connected to an initial signal line, a second electrode connected to the first electrode of the light emitting unit and a gate electrode connected to a first reset signal line; and
a second transistor, comprising a first electrode connected to the gate electrode of the driving transistor, a second electrode connected to the second electrode of the driving transistor and a gate electrode connected to a first gate line,
the display panel further comprises:
a second active layer, provided on a side, away from the base substrate, of the first conductive layer, and comprising a first active part for forming a channel region of the first transistor and a second active part for forming a channel region of the second transistor;
a third conductive layer, provided on a side, away from the base substrate, of the second active layer;
a fourth conductive layer, provided on a side, away from the base substrate, of the third conductive layer; and
a fifth conductive layer, provided on a side, away from the base substrate, of the fourth conductive layer, the fifth conductive layer comprising the power line, the power line comprising a first extension part and a second extension part, a dimension, in the first direction, of an orthographic projection of the first extension part on the base substrate being larger than a dimension, in the first direction, of an orthographic projection of the second extension part on the base substrate, and the orthographic projection of the first extension part on the base substrate covering an orthographic projection of the first active part on the base substrate and an orthographic projection of the second active part on the base substrate.

17. The display panel according to claim 1, wherein the pixel driving circuit further comprises:
a first transistor, comprising a first electrode connected to an initial signal line, a second electrode connected to the first electrode of the light emitting unit and a gate electrode connected to a first reset signal line; and
a second transistor, comprising a first electrode connected to the gate electrode of the driving transistor, a second electrode connected to the second electrode of the driving transistor and a gate electrode connected to a first gate line,
the display panel further comprises:
a second active layer, provided on a side, away from the base substrate, of the first conductive layer, and comprising a first active part for forming a channel region of the first transistor and a second active part for forming a channel region of the second transistor; and
a second conductive layer, provided between the first conductive layer and the second active layer, the second conductive layer comprising:
a third gate line, an orthographic projection of the third gate line on the base substrate extending in the first direction and covering an orthographic projection of the second active part on the base substrate, and a part of the third gate line being configured to form a bottom gate of the second transistor; and
a second reset signal line, an orthographic projection of the second reset signal line on the base substrate extending in the first direction and covering an orthographic projection of the first active part on the base substrate, and a part of the second reset signal line is configured to form a bottom gate of the first transistor.

18. The display panel according to claim 1, further comprising:
an electrode layer, provided on a side, away from the base substrate, of the first conductive layer, and comprising a plurality of electrode parts, the electrode part being configured to form the first electrode of the light emitting unit,
the plurality of electrode parts comprises a plurality of R electrode parts, a plurality of G electrode parts, and a plurality of B electrode parts,
in a plurality of electrode parts connected to a same row of the pixel driving circuits, the R electrode part, the G electrode part, the B electrode part, the G electrode part are arranged in a row direction in turn,
in two adjacent columns of the pixel driving circuits, a plurality of R electrode parts and a plurality of B electrode parts are connected to a same column of the pixel driving circuits, the R electrode part and the B electrode part connected to the same column of the pixel driving circuits are arranged in a column direction in turn, and a plurality of G electrode parts are connected to another column of the pixel driving circuits,
a minimum distance, in the column direction, between orthographic projections, on the base substrate, of two G electrode parts at least partially connected to adjacent rows of the pixel driving circuits and connected to a same column of the pixel driving circuits is less than a dimension, in the column direction, of an orthographic projection of the R electrode part on the base substrate or a dimension, in the column direction, of the orthographic projection of the B electrode part on the base substrate.

19. The display panel according to claim 1, further comprising:
an electrode layer, provided on a side, away from the base substrate, of the first conductive layer, and comprising a plurality of electrode parts, the electrode part being configured to form the first electrode of the light emitting unit,
the plurality of electrode parts comprises a plurality of R electrode parts, a plurality of G electrode parts, and a plurality of B electrode parts,
in a plurality of electrode parts connected to a same row of the pixel driving circuits, the R electrode part, the G electrode part, the B electrode part, the G electrode part are arranged in a row direction in turn,
in two adjacent columns of the pixel driving circuits, a plurality of R electrode parts and a plurality of B electrode parts are connected to a same column of the pixel driving circuits, the R electrode part and the B electrode part connected to the same column of the pixel driving circuits are arranged in a column direction in turn, and a plurality of G electrode parts are connected to another column of the pixel driving circuits,
a minimum distance, in the column direction, between orthographic projections, on the base substrate, of two G electrode parts at least partially connected to adjacent rows of the pixel driving circuits and connected to a same column of the pixel driving circuits is greater than a dimension, in the column direction, of an orthographic projection of the R electrode part on the base substrate or a dimension, in the column direction, of the orthographic projection of the B electrode part on the base substrate.

20. A display device comprising a display panel, wherein the display panel comprises a light emitting unit and a pixel driving circuit for driving the light emitting unit, and the pixel driving circuit comprises:
a driving transistor;
a fifth transistor, comprising a first electrode connected to a power line, a second electrode connected to a first electrode of the driving transistor and a gate electrode connected to a first enabling signal line; and
a sixth transistor, comprising a first electrode connected to a second electrode of the driving transistor, a second electrode connected to a first electrode of the light emitting unit and a gate electrode connected to a second enabling signal line,
the display panel further comprises:
a base substrate;
a first active layer, provided on a side of the base substrate, the first active layer comprising a third active part, a fifth active part, a sixth active part, the third active part being configured to form a channel region of the driving transistor, the fifth active part being configured to form a channel region of the fifth transistor, and the sixth active part being configured to form a channel region of the sixth transistor; and
a first conductive layer, provided on a side, away from the base substrate, of the first active layer, wherein the first conductive layer comprises:
the first enabling signal line, an orthographic projection of the first enabling signal line on the base substrate extending in a first direction and covering an orthographic projection of the fifth active part on the base substrate, and a part of the first enabling signal line being configured to form the gate electrode of the fifth transistor;
the second enabling signal line, an orthographic projection of the second enabling signal line on the base substrate extending in the first direction and covering an orthographic projection of the sixth active part on the base substrate, and a part of the second enabling signal line being configured to form a gate electrode of the sixth transistor; and
a first conductive part, an orthographic projection of the first conductive part on the base substrate covering the third active part, and the first conductive part being configured to form the gate electrode of the driving transistor.
